(19) United States
(12) Patent Application Publication
(10) Pub. No.: US 2024/0302099 A1
(43) Pub. Date: Sep. 12, 2024

(54) WAFER STORAGE CONTAINER DRYING APPARATUS AND CLEANING SYSTEM

(71) Applicant: SHIBAURA MECHATRONICS CORPORATION, Kanagawa (JP)

(72) Inventors: Junji ISHIHARA, Kanagawa (JP); Hisaaki MIYASAKO, Kanagawa (JP); Yukinobu NISHIBE, Kanagawa (JP)

(21) Appl. No.: 18/583,578

(22) Filed: Feb. 21, 2024

(30) Foreign Application Priority Data
Mar. 6, 2023 (JP) 2023-034004

(51) Int. Cl. F26B 25/00; B08B 9/20; F26B 3/02

(52) U.S. Cl. CPC F26B 25/003; B08B 9/20; F26B 3/02; B08B 2209/08

(57) ABSTRACT

According to one embodiment of the present disclosure, a wafer storage container drying apparatus includes a drying tank for drying a wafer storage container that has a storage space connected to an opening and configured to store a wafer, and includes a body including a flange gripped by a robot, and a door installed to be openable and closable with respect to the opening, wherein the drying tank includes a carrying-in/out port configured to be openable and closable by an opening and closing cover, a body receiver configured to receive the body of the wafer storage container in a state where the flange faces the carrying-in/out port; and a door holder configured to hold the door such that each side of the door is neither orthogonal nor parallel to one side that forms the carrying-in/out port, when the drying tank is viewed in a plan view.

### CROSS-REFERENCE TO RELATED APPLICATIONS

This application is based on and claims priority from Japanese Patent Application No. 2023-034004 filed on Mar. 6, 2023, with the Japan Patent Office, the disclosure of which is incorporated herein in its entirety by reference.

### TECHNICAL FIELD

Embodiments of the present disclosure relate to a wafer storage container drying apparatus and a cleaning system.

### BACKGROUND

In the related art, there is a cleaning system for cleaning and drying wafer storage containers such as front opening unified pods (FOUP) or front opening shipping boxes (FOSB) that accommodate semiconductor wafers.

The wafer storage container is transferred into the cleaning system, and a robot transfers the wafer storage container to a cleaning tank while grasping the wafer storage container. Then, the cleaning tank performs cleaning on the wafer storage container. In addition, the cleaned wafer storage container is dried in the same cleaning tank. Subsequently, the dried wafer storage container is carried out of the cleaning system.

### SUMMARY

Here, an upper surface of a wafer storage container body is provided with a flange that enables a robot hand to grip the wafer storage container body. The wafer storage container is disposed in the cleaning tank while the flange faces a side surface of the cleaning tank (for example, while facing an opening where a door of the wafer storage container fits in downward), and cleaned and dried in the tank. This is because the flange is provided on the surface intersecting the opening, so the flange should be disposed to face the side surface of the cleaning tank for convenience of drainage in a wafer storage space. Therefore, when the robot hand transfers the wafer storage container body in the cleaning tank, a predetermined space is required to enable the robot hand to enter between the side surface of the cleaning tank and the flange (for example, which corresponds to the “extension portion 11” in Japanese Patent Laid-Open Publication No. 2005-109523). For this reason, the volume of an internal space of the cleaning tank increases.

The present disclosure is made to solve the above problems, and an object of the present disclosure is to provide a wafer storage container drying apparatus and a cleaning system allowing for an improvement in drying efficiency.

In order to solve the above-described problems and achieve the object, a wafer storage container drying apparatus according to one aspect of the present disclosure includes a drying tank for drying a wafer storage container that has a storage space connected to an opening and configured to store a wafer, and includes a flange gripped by a robot, and a door installed to be openable and closable with respect to the opening. The drying tank includes a carrying-in/out port that is openable and closable by an opening and closing cover; a body receiving unit that receives the body of the wafer storage container in a state where the flange faces the carrying-in/out port; and a door holding unit that is provided closer to the carrying-in/out port of the body receiving unit than the body of the wafer storage container in a state where the body of the the wafer storage container is received in the body receiving unit, and holds the door such that each side of the door is neither orthogonal nor parallel to one side that forms the carrying-in/-out port, when the drying tank is viewed in a plan view.

Furthermore, in order to solve the above-described problems and achieve the object, a cleaning system according to one aspect of the present disclosure includes the wafer storage container drying apparatus and a cleaning tank for cleaning the wafer storage container, and the drying tank dries the wafer storage container cleaned in the cleaning tank.

According to one aspect of the present disclosure, it is possible to provide a wafer storage container drying apparatus and a cleaning system capable of improving drying efficiency.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating an example of a schematic configuration of a wafer storage container cleaning apparatus according to an embodiment.

FIG. 2 is a side perspective view of an inside of a wafer storage container drying apparatus according to an embodiment.

FIG. 3 is a plan view of a front opening unified pod (FOUP) body holding unit according to an embodiment.

FIG. 4 is a plan view (top view) of a drying tank according to an embodiment.

### DESCRIPTION OF EMBODIMENTS

In the following detailed description, reference is made to the accompanying drawings, which form a part of the present disclosure. The illustrative embodiments described in the detailed description, drawings, and claims are not meant to be limiting. Other embodiments may be utilized, and other changes may be made without departing from the spirit or scope of the subject matter presented herein.

Hereinafter, with reference to the accompanying drawings, embodiments of a wafer storage container drying apparatus and a cleaning system disclosed in the present disclosure will be described in detail. In addition, the wafer storage container drying apparatus disclosed in the present disclosure is not limited to the following embodiments. In the following embodiment, a case where a wafer storage container to be cleaned and dried is a front opening unified pod (FOUP) will be described by way of example. However, the wafer storage container to be cleaned and dried is not limited thereto. For example, the wafer storage container to be cleaned and dried may be a front opening shipping box (FOSB).

### EMBODIMENT

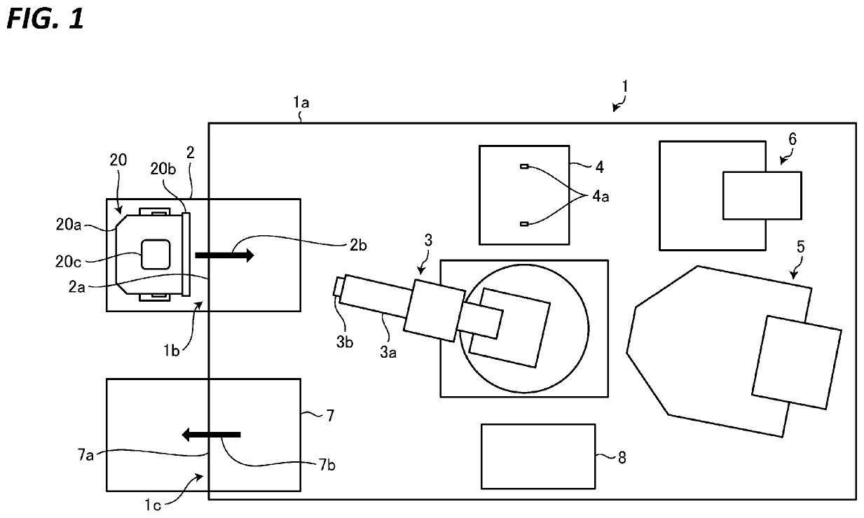

FIG. 1 is a plan view illustrating an example of a schematic configuration of a cleaning system 1 according to an embodiment. The cleaning system 1 is installed, for example, in a factory that manufactures semiconductor wafers, and cleans and dries wafer storage containers.

As illustrated in FIG. 1, the cleaning system 1 includes a load port 2, a robot 3, a disassembly/connection stage 4, a cleaning tank 5, a wafer storage container drying apparatus 6, an unload port 7, and a controller 8.

The robot 3, the disassembly/connection stage 4, the cleaning tank 5, the wafer storage container drying apparatus 6, and the controller 8 are provided inside a casing 1a of the cleaning system 1. Meanwhile, the load port 2 and the unload port 7 are provided inside and outside the casing 1a of the cleaning system 1.

The load port 2 carries a FOUP 20 to be cleaned and dried, which is disposed outside the casing 1a of the load port 2, into an inside of the casing 1a. The FOUP 20 includes a FOUP body 20a and a door 20b. The FOUP body 20a has an opening (FOUP body opening) and a storage space for storing semiconductor wafers. The storage space is located inward from the FOUP body opening and is in communication with the FOUP body opening. The FOUP door 20b may be disassembled/connected with the FOUP body 20a and is installed to be openable and closable with respect to the FOUP body opening when connected with the FOUP body 20a. The FOUP body 20a is an example of a main body. The FOUP body 20a is provided with a flange 20c. The flange 20c is a portion that is grasped (held) when the FOUP 20 is transferred by an overhead hoist transfer (OHT) or the robot 3 and is provided on a surface that intersects with a surface of the FOUP body 20a where the FOUP body opening is formed.

For example, in the outside of the casing 1a of the load port 2, the FOUP 20 transferred by the OHT is disposed. For example, as illustrated in FIG. 1, the FOUP 20 is disposed such that the FOUP door 20b of the FOUP 20 faces a shutter 2a provided in an opening 1b of the casing 1a. In this manner, when the FOUP 20 is disposed in the load port 2, the shutter 2a is raised. Accordingly, the FOUP 20 may be carried into the inside of the casing 1a from the opening 1b. That is, the FOUP 20 may be carried into the inside of the cleaning system 1. Then, the FOUP 20 is slid by a sliding device of the load port 2 in a direction of an arrow 2b. Accordingly, the FOUP 20 is carried into the inside of the casing 1a.

Now, sliding by the sliding device will be described. For example, a pin provided in the sliding device is inserted into a hole formed in a bottom (placement surface) of the FOUP 20 so that the placement surface of the FOUP 20 is fixed to the sliding device. In this state, as the sliding device is slid in the direction of the arrow 2b, the FOUP 20 is slid along with the sliding device. Accordingly, the FOUP 20 is disposed on a predetermined portion of the load port 2 inside the casing 1a. When the FOUP 20 is thus carried into the inside of the casing 1a, the shutter 2a is lowered to close the opening 1b of the casing 1a. The sliding device, together with the pin, is lowered to a position lower than a bottom of the shutter 2a (the placement surface of the FOUP 20) and returns to its original position outside the casing 1a.

The robot 3 transfers the FOUP 20 to each part while grasping the flange 20c of the FOUP 20. The robot 3 includes a robot arm 3a and a robot hand 3b (a gripping portion of the robot 3). The robot 3 stretches or rotationally moves the robot arm 3a while grasping the flange 20c by the robot hand 3b to transfer the FOUP 20 to each part. In addition, when the robot 3 transfers a single FOUP door 20b that has been separated (disassembled) from the FOUP body 20a, the robot 3 grips both sides of the FOUP door 20b to transfer the FOUP door 20b.

The disassembly/connection stage 4 disassembles (separates) the FOUP 20 into the FOUP body 20a and the FOUP door 20b, or connects the FOUP body 20a and the FOUP door 20b. On the disassembly/connection stage 4, latch keys 4a are provided. By rotating the FOUP 20 in a state where the latch keys 4a are inserted into keyholes formed in the FOUP door 20b of the FOUP 20, the FOUP 20 is disassembled into the FOUP body 20a and the FOUP door 20b, or the FOUP body 20a and the FOUP door 20b are connected to each other. For example, in the disassembly/connection stage 4, the FOUP 20 that is carried into the inside of the casing 1a is transferred by the robot 3. In this case, the disassembly/connection stage 4 disassembles the FOUP 20 into the FOUP body 20a and the FOUP door 20b. Further, disassembling may be referred to as unlocking, and connecting may be referred to as locking.

The cleaning tank 5 is a tank for cleaning the FOUP 20. For example, in the cleaning tank 5, the FOUP body 20a and the FOUP door 20b are separately transferred by the robot 3. Then, the cleaning tank 5 performs cleaning on the FOUP 20 while holding the FOUP body 20a and the FOUP door 20b separately. For example, the cleaning tank 5 performs cleaning of the FOUP 20 by holding the FOUP door 20b on a cover portion of the cleaning tank 5 and the FOUP body 20a on a tank portion of the cleaning tank 5 (a cleaning tank body of the cleaning tank 5) and discharging a cleaning liquid (e.g., deionized water) to each of the FOUP body 20a and the FOUP door 20b through a cleaning liquid nozzle while rotating them by a rotating mechanism (not illustrated). In this case, it is preferable to dispose the FOUP body opening of the FOUP body 20a to face downward in the cleaning tank 5 in consideration of discharge properties of the cleaning liquid.

When the cleaning of the FOUP 20 is completed in the cleaning tank 5, the FOUP body 20a and the FOUP door 20b continue to be rotated in the cleaning tank 5 and are dried therein by spraying dry air. Here, the drying in the cleaning tank 5 is a treatment (pre-drying) that roughly dries the cleaning liquid that is attached to the FOUP 20. When the pre-drying of the FOUP 20 is completed in the cleaning tank 5, the robot 3 transfers the FOUP body 20a and the FOUP door 20b in the cleaning tank 5 separately to the wafer storage container drying apparatus 6.

The wafer storage container drying apparatus 6 is an apparatus for vacuum-drying (main drying) of the FOUP 20. When the vacuum-drying of the FOUP 20 is completed in the wafer storage container drying apparatus 6, the robot 3 transfers the FOUP body 20a and the FOUP door 20b in the wafer storage container drying apparatus 6 separately to the disassembly/connection stage 4. Then, the disassembly/connection stage 4 connects the FOUP body 20a and the FOUP door 20b. Furthermore, details of the wafer storage container drying apparatus 6 will be described later.

The unload port 7 carries the FOUP 20 (whose cleaning and vacuum-drying has been completed) that is disposed in the inside of the casing 1a of the unload port 7 by the robot 3, to the outside of the casing 1a.

For example, in the unload port 7 inside the casing 1a, after the vacuum-drying, the FOUP 20 with the FOUP body 20a and the FOUP door 20b that are connected in the disassembly/connection stage 4 is transferred by the robot 3 and disposed therein. When the FOUP 20 is disposed in the unload port 7 in this manner, the shutter 7a provided in the opening 1c of the casing 1a is raised. Accordingly, the FOUP 20 may be carried out to the outside of the casing 1a from the opening 1c. That is, the FOUP 20 may be carried out to the outside of the cleaning system 1. Then, the FOUP 20 is slid in a direction of an arrow 7b by a sliding device of the unload port 7 (which has the same mechanism as the sliding device of the load port 2), whereby the FOUP 20 is carried out to the outside of the casing 1a. When the FOUP 20 is carried out to the outside of the casing 1a, the shutter 7a is lowered to close the opening 1c of the casing 1a.

The controller 8 controls an overall operation of the cleaning system 1. For example, the controller 8 controls the load port 2, the robot 3, the disassembly/connection stage 4, the cleaning tank 5, the wafer storage container drying apparatus 6, and the unload port 7 to operate the load port 2, the robot 3, the disassembly/connection stage 4, the cleaning tank 5, the wafer storage container drying apparatus 6, and the unload port 7, as described above.

For example, the controller 8 has a communication interface with a central processing unit (CPU), a read only memory (ROM), a random access memory (RAM), and a hard disk drive (HDD). They are connected via an internal bus.

The CPU executes various processes by using a memory area of the RAM as a temporary storage area for data used in various processes. The ROM and HDD store programs for executing various processes and various databases or tables used for executing various processes. The communication interface is an interface for communicating with each of the above-described parts of the cleaning system 1 and for communicating with external devices connected to the cleaning system 1 via a network. For example, the communication interface is a network interface card.

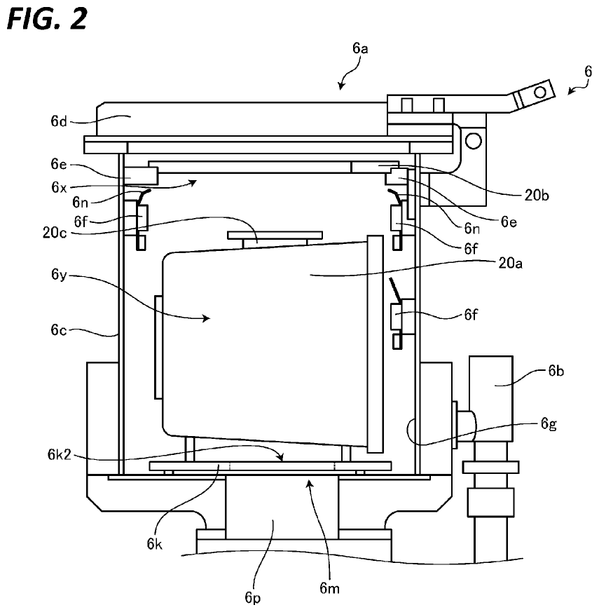

Next, an example of the wafer storage container drying apparatus 6 according to this embodiment will be described. FIG. 2 is a side perspective view of an inside of the wafer storage container drying apparatus 6 according to an embodiment. FIG. 2 is a schematic diagram of the wafer storage container drying apparatus 6. In the example of FIG. 2, a side of a portion of the wafer storage container drying apparatus 6 is not illustrated, but rather, an interior of a drying tank 6a of the wafer storage container drying apparatus 6 is illustrated. Also, in the example of FIG. 2, a state where an opening (a drying tank opening) 6x of a drying tank body 6c is closed by an opening and closing cover 6d of the drying tank 6a.

As illustrated in FIG. 2, the wafer storage container drying apparatus 6 includes the drying tank 6a, a roughing valve (connected to a dry pump) 6b, an exhaust port 6g connected to the roughing valve 6b, an exhaust pipe 6p, a turbo molecular pump and a main valve (not illustrated) connected to the exhaust pipe 6p at a bottom of the exhaust pipe 6p.

The drying tank 6a vacuum-dries the FOUP 20. Specifically, the drying tank 6a vacuum-dries the FOUP 20 that has been cleaned in the cleaning tank 5. The drying tank 6a includes the drying tank body 6c, the opening and closing cover (lid) 6d, door holding units 6e, heaters 6f, reflectors 6n, and a FOUP body holding unit 6k.

Here, in the drying tank 6a, it is unnecessary to dispose the FOUP body opening of the FOUP body 20a to face downward because there is no need to consider discharge properties of the cleaning liquid as in the cleaning tank 5. Furthermore, it is preferable to make the volume of an internal space of the drying tank 6a as small as possible for vacuum exhaust. Therefore, the drying tank 6a according to this embodiment is configured as described below to make the volume of the internal space as small as possible.

The drying tank body 6c has the drying tank opening 6x in an upper portion thereof and a drying space 6y in which the FOUP body 20a is disposed. Specifically, for example, an internal space of the drying tank body 6c is an area including the drying tank opening 6x and the drying space 6y. The opening and closing cover 6d is provided on a top of the drying tank body 6c. Specifically, the opening and closing cover 6d is provided to be openable and closable with respect to the drying tank opening 6x of the drying tank body 6c. The opening and closing cover 6d is configured to open and close the drying tank opening 6x of the drying tank body 6c by, for example, operating an air cylinder. In other words, the drying tank opening 6x may be opened and closed by the opening and closing cover 6d.

The drying space 6y inside the drying tank body 6c is located inward from the drying tank opening 6x and is in communication with the drying tank opening 6x. The FOUP body 20a is carried into the drying space 6y from the drying tank opening 6x by the robot 3 in a state where the opening and closing cover 6d is opened with respect to the drying tank opening 6x. At this time, the robot 3 carries the FOUP body 20a into the drying space 6y in a state where the flange 20c faces upward. In the drying space 6y of the drying tank body 6c, the FOUP body holding unit 6k is provided to hold the carried-in FOUP body 20a. Here, the FOUP body holding unit 6k holds the FOUP body 20a in a state where the flange 20c of the FOUP body 20a faces upward. That is, the FOUP body holding unit 6k holds the FOUP body 20a in a state where the flange 20c faces toward the drying tank opening 6x of the drying tank body 6c. Further, the FOUP body holding unit 6k holds the FOUP body 20a in a state where the opening of the FOUP body 20a faces a side wall (a side surface) of the drying tank body 6c. In this manner, the FOUP body holding unit 6k holds the FOUP body 20a, so that the FOUP body 20a is received in the drying space 6y of the drying tank body 6c. The drying space 6y of the drying tank body 6c is an example of a body receiving unit for receiving the FOUP body 20a.

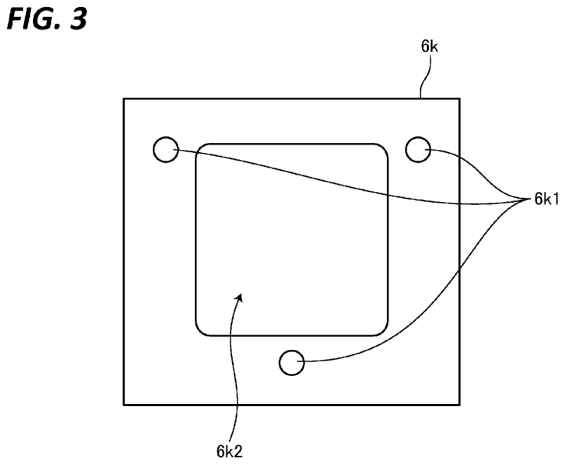

FIG. 3 is a plan view of a front opening unified pod (FOUP) body holding unit 6k according to an embodiment. As illustrated in FIG. 3, the FOUP body holding unit 6k is a plate-like member and is provided with a plurality of pins (kinematic pins) 6k1. These pins 6kl are installed in positions corresponding to holes formed in a bottom of the FOUP body 20a (the surface of the FOUP body 20a opposing the surface thereof on which the flange 20c is provided). The positions of the holes formed in the bottom of the FOUP body 20a are predetermined by a standard.

The FOUP body holding unit 6k holds the FOUP body 20a by forming a gap between the bottom of the FOUP body 20a and the FOUP body holding unit 6ka through the plurality of pins 6k1. A hole 6k2 is formed in the FOUP body holding unit 6k, and through the hole 6k2, an exhaust port 6m formed in the drying tank body 6c (see FIG. 2) and a lower space of the bottom of the FOUP body 20a are in communication with each other. Specifically, the exhaust port 6m and the exhaust pipe 6p are connected to each other. By allowing the lower space of the FOUP body 20a and the exhaust port 6m to be in communication with each other in this manner, the FOUP body holding unit 6k is configured not to interrupt exhaust from the exhaust port 6m. Accordingly, exhaust efficiency of the drying tank 6a is improved, and furthermore, drying efficiency of the drying tank 6a is improved.

As described above, the robot 3 carries the FOUP body 20a into the drying space 6y in a state where the flange 20c faces upward. Because of this, it is not necessary to leave a relatively large space for the robot 3 (more specifically, the robot hand 3b) to enter between the side surface of the drying tank body 6c and the FOUP body 20a, so that a gap between the side surface of the drying tank body 6c and the FOUP body 20a may be narrower compared to the case of the cleaning tank 5. In other words, a size of an internal volume (e.g., a volume of a space combining the drying tank opening 6x and the drying space 6y) of the drying tank body 6c may be made such that the FOUP body 20a fits therein with no extra space. Therefore, with the wafer storage container drying apparatus 6 according to this embodiment, it is possible to suppress an increase in the volume of the internal space of the drying tank 6a.

By suppressing the increase in the volume of the drying tank 6a, it is possible to evacuate the internal space of the drying tank 6a rapidly and shorten the time to evacuate to a target vacuum degree. Accordingly, drying process efficiency of the FOUP 20 may be improved.

In addition, as described above, the FOUP 20 carried into the drying tank 6a has already been pre-dried in the cleaning tank 5 and is intended to be dried (subjected to main drying) in the drying tank 6a more reliably.

The door holding unit 6e is provided in the drying tank opening 6x to hold the FOUP door 20b that is transferred by the robot 3. In this embodiment, two door holding units 6e are installed as illustrated in FIG. 2, but the number of door holding units 6e is not limited thereto.

In this embodiment, after the FOUP body 20a is carried into the drying space 6y by the robot 3 in a state where the opening and closing cover 6d opens with respect to the drying tank opening 6x, the FOUP door 20b is carried into the drying tank opening 6x. The door holding units 6e holds the FOUP door 20b that is thus carried in. Further, after vacuum-drying of the FOUP 20 is completed, the FOUP door 20b held by the door holding units 6e is carried out by the robot 3. In this manner, the FOUP door 20b is carried via the drying tank opening 6x by the robot 3. Then, the FOUP body 20a held by the FOUP body holding unit 6k is carried out by the robot 3. Thus, the drying tank opening 6x is both an inlet and an outlet (that is, an opening in which the FOUP 20 is carried in and out by the robot). Thus, the drying tank opening 6x is an example of a carrying-in/-out port.

In addition, in a state where the FOUP body 20a is held by the FOUP body holding unit 6k, the exhaust port 6g for evacuating the internal space of the drying tank 6a (for example, for making the internal space of the drying tank 6a in a vacuum state) is formed at a position of a side wall (side surface) of the drying tank 6a, which opposes the opening of the FOUP body 20a. In the wafer storage container drying apparatus 6 of this embodiment, the FOUP body 20a is held by the FOUP body holding unit 6k, and the FOUP door 20b is held by the door holding units 6e. In a state where the drying tank opening 6x is closed by the opening and closing cover 6d, the internal space of the drying tank body 6c is heated by the heaters 6f while forming a vacuum (rough pumping) through the exhaust port 6g and the roughing valve 6b, and forming a vacuum (main pumping) by the turbo molecular pump through the exhaust port 6m, the exhaust pipe 6p, and the main valve, so that the FOUP body 20a and the FOUP door 20b are vacuum-dried. Here, the reflector 6n reflects heat from the heater 6f such that the heat from the heater 6f spreads throughout the internal space of the drying tank body 6c. Accordingly, the internal space of the drying tank body 6c may be efficiently heated.

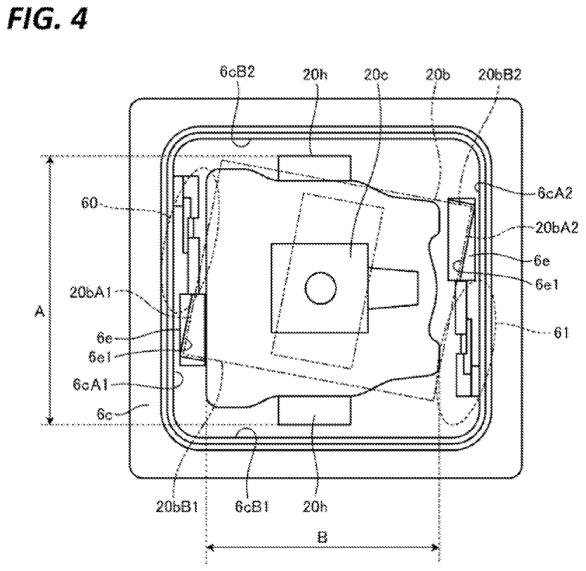

Next, the door holding units 6e according to this embodiment will be described. FIG. 4 is a plan view (top view) of the drying tank 6a according to an embodiment. However, the opening and closing cover 6d is not illustrated in FIG. 4. Also, in FIG. 4, the FOUP door 20b is illustrated as a dash-double dotted line. FIG. 4 is a schematic view of components of the wafer storage container drying apparatus 6. When the drying tank 6a is viewed in plan view (top view) as illustrated in FIG. 4, a shape of the FOUP door 20b is a square or approximately a square formed by four sides 20bA1, 20bA2, 20bB1, and 20bB2. A length of short sides 20bA1 and 20bA2 is about 80% of a length of long sides 20bB1 and 20bB2. In addition, when viewed in the plan view, a shape of side surfaces that form the drying tank opening 6x of the drying tank body 6c is also a square or approximately a square formed by four sides 6cA1, 6cA2, 6cB1, and 6cB2.

In this manner, the shape of the FOUP door 20b and the shape of the drying tank opening 6x may be considered to be a square or approximately a square. Furthermore, in this embodiment, when the FOUP body 20a is held by the FOUP body holding unit 6k, a length A of the FOUP body 20a in a direction parallel to a direction in which the side 6cA1 extends is slightly greater than a length B of the FOUP body 20a in a direction parallel to a direction in which the side 6cB1 extends. This is because the FOUP body 20a has two handles 20h in the direction parallel to the direction in which the side 6cB1 extends, as illustrated in FIG. 4.

Furthermore, in this embodiment, the length of the side 20bB1 of the FOUP door 20b is about the same as the length A described above, and the length of the side 20bA1 of the FOUP door 20b is about 80% of the side 20bB1 of the FOUP door 20b as described above and thus, is approximately shorter than the length A. For example, the length of the side 20bA1 of the FOUP door 20b is 307 mm and the length of the side 20bB1 is 365 mm.

In this embodiment, as illustrated in FIG. 4, when the drying tank 6a is viewed in the plan view, the door holding unit 6e holds the FOUP door 20b such that each side of the FOUP door 20b is neither orthogonal nor parallel to one side which forms the drying tank opening 6x. For example, the door holding unit 6e holds the FOUP door 20b such that the side 20bA1 is neither orthogonal nor parallel to the side 6cA1. Further, the door holding unit 6e holds the FOUP door 20b such that the side 20bA2 is neither orthogonal or parallel to the side 6cA2. Further, the door holding unit 6e holds the FOUP door 20b such that the side 20bB1 is neither orthogonal nor parallel to the side 6cB1. Further, the door holding unit 6e holds the FOUP door 20b such that the side 20bB2 is neither orthogonal nor parallel to the side 6cB2.

The door holding unit 6e has a step 6e1 formed to follow a corner of the FOUP door 20b, which has a square or approximately square shape when viewed in a plan view. The step 6e1 is formed in the door holding unit 6e such that the step 6e1 is inclined with respect to the sides 6cA1 and 6cA2 when the step 6e1 is viewed in a plan view. In other words, the step 6e1 is formed in the door holding unit 6e such that the step 6e1 is neither orthogonal nor parallel to the sides 6cA1 and 6cA2 when the step 6e1 of the door holding unit 6e is viewed in a plan view.

Here, descriptions will be made on, for example, a case where the door holding units 6e holds the FOUP door 20b such that each side of the FOUP door 20b is either orthogonal or parallel to one side which forms the drying tank opening 6x. In this case, for example, the door holding units 6e hold the FOUP door 20b such that the side 20bA1 is parallel to the side 6cA1. Further, the door holding units 6e hold the FOUP door 20b such that the side 20bA2 is parallel to the side 6cA2. Further, the door holding unit 6e holds the FOUP door 20b such that the side 20bB1 is parallel to the side 6cB1. Further, the door holding unit 6e holds the FOUP door 20b such that the side 20bB2 is parallel to the side 6cB2. In this manner, when it is intended to hold the FOUP door 20b by the door holding units 6e, positions of the door holding units 6e are located inward compared to positions of the door holding units 6e illustrated in FIG. 4. In this case, even if the robot 3 intends to carry the FOUP body 20a into the drying space 6y, the door holding units 6e and the FOUP body 20a interfere with each other, making it difficult to carry the FOUP body 20a into the drying space 6y.

According to this embodiment, the door holding units 6e, as described above, holds the FOUP door 20b such that each side of the FOUP door 20b is neither orthogonal or parallel to one side which forms the drying tank opening 6x. Diagonals of the FOUP door 20b are longer than the long sides 20bB1 and 20bB2 of the FOUP door 20b. Because of this, compared to a case where long sides 20bB1 and 20bB2 of the FOUP door 20b are disposed in parallel with sides 6cB1 and 6cB2 of the drying tank opening 6x, when the FOUP door 20b is obliquely disposed, the length of the sides 6cB1 and 6cB2 may be increased. Furthermore, the length B of the FOUP body 20a in a direction following the sides 6cB1 and 6cB2 is approximately equal to the length of the sides 20bB1 and 20bB2 of the FOUP door 20b. Accordingly, as illustrated in FIG. 4, corners of the FOUP door 20b at the sides 6cB1 and 6cB2 may be disposed on an outer side (a side closer to the sides 6cA1 and 6cA2) than an area where the FOUP body 20a is disposed. By disposing the door holding units 6e adjacent to the sides 6cA1 and 6cA2 to support the corners of the FOUP door 20b, a space may be secured between a pair of the door holding units 6e to allow the FOUP body 20a to pass therethrough. Since it is possible to secure this space, there is no need to install an evacuation mechanism in the door holding units 6e in order to avoid interference between the door holding units 6e and the FOUP body 20a when the FOUP body 20a is carried in and out. Thus, it is possible to facilitate carrying in and out the FOUP body 20a and the FOUP door 20b with a simple configuration.

In addition, in order to prevent interference between the door holding units 6e and the FOUP body 20a, it is conceivable that the drying tank 6a holds the FOUP body 20a and the FOUP door 20b such that the FOUP door 20b is disposed at a position lower than that of the FOUP body 20a in the internal space of the drying tank 6a. However, in this case, in order to position the FOUP door 20b on a bottom of the drying tank 6a, it is necessary to bring the robot 3 (more specifically, the robot arm 3a) to the bottom of the drying tank 6a. This increases the possibility that the robot 3 (more specifically, the robot arm 3a) may come into contact with the drying tank 6a, thereby increasing the risk that the robot arm 3a may damage components in the drying tank 6a. Meanwhile, in the internal space of the drying tank 6a, as in this embodiment, when the FOUP body 20a is disposed to be lower than the FOUP door 20b in a state where the flange 20c faces upward, a deepest position from a position where the robot 3 enters the drying tank 6a becomes a position of the flange 20c. As such, in this embodiment, since the robot 3 only needs to move to the flange 20c at a relatively shallow position, the risk that the robot 3 comes into contact with the drying tank 6a may be reduced.

Furthermore, in this embodiment, two door holding units 6e are provided, as illustrated in FIG. 4. By combining the steps of the two door holding units 6e and two corners on the diagonal (diagonal corners) among the four corners of the FOUP door 20b, the two door holding units 6e hold the two diagonal corners of the FOUP door 20b. In this manner, the two diagonal corners of the FOUP door 20b are held by the door holding units 6e, so that a position of the FOUP door 20b with respect to the drying tank 6a may be determined.

Also, by obliquely disposing the long sides 20bB1 and 20bB2 of the FOUP door 20b, rather than disposing them in parallel with the sides 6cB1 and 6cB2 of the drying tank opening 6x, as illustrated in FIG. 4, gaps 60 and 61 are naturally formed between each of the two opposing sides 6cA1 and 6cA2 which form the drying tank opening 6x and the FOUP door 20b that is held by the door holding units 6e. The gaps 60 and 61 are spaces for enabling the FOUP door 20b to be held by the robot 3 (spaces in which the robot arm 3a is inserted). Accordingly, in this embodiment, a distance between the sides 6cA1 and 6cA2 may be made such that the FOUP body 20a is able to be carried in and out, and the robot 3 may enter the gaps 60 and 61 and grip the FOUP door 20b. Accordingly, an increase in the volume of the drying tank 6a may be suppressed.

As described above, the two door holding units 6e according to this embodiment are provided in the vicinity of the two opposing sides (sides 6cA1 and 6cA2) forming the drying tank opening 6x, respectively. A space between the two door holding units 6e has a size such that the FOUP body 20a may be carried into the drying space 6y in a state where the flange 20c faces upward and the FOUP body 20a may be carried out of the drying space 6y.

Furthermore, depending on a type of the FOUP 20, a size of the FOUP door 20b may be different. For this reason, the controller 8 may automatically adjust the position of the door holding unit 6e according to the type of the FOUP 20. Accordingly, the door holding units 6e may hold FOUP doors 20b of various sizes. Also, the position of the door holding unit 6e may be adjusted manually by a user.

As above, the wafer storage container drying apparatus 6 and the cleaning system 1 according to an embodiment have been described. As described above, with the wafer storage container drying apparatus 6 and the cleaning system 1, it is possible to suppress an increase in the volume of the internal space of the drying tank 6a, thereby improving drying efficiency.

Here, since the FOUP 20 is formed of a resin material and has low heat resistance, it is necessary to maintain a temperature setting of the heater 6f, for example, at about 90 degrees or less. In other words, since there is an upper limit to the temperature setting of the heater 6f, there is a limit to improving drying efficiency of the FOUP 20 by increasing the set temperature of the heater 6f. In a case where the inner space of the drying tank 6a has a smaller volume, it is possible to heat the inner space rapidly even in a situation where there is an upper limit to the temperature setting, so that the FOUP 20 may be dried rapidly.

Furthermore, when drying the FOUP 20 under a vacuum, such as in the drying tank 6a of the above-described embodiment, it is possible to dry the FOUP 20 rapidly since the time required for evacuation may be shortened in a case where the inner space of the drying tank 6a has a smaller volume. In other words, it is possible to improve drying efficiency by suppressing an increase in the volume of the inner space of the drying tank 6a.

In the above embodiment, deionized water is exemplified as the cleaning liquid, but the present disclosure is not limited thereto, and a cleaning liquid including a surfactant or a liquid having a gas dissolved therein may also be used. Two fluid nozzles may be used to supply two different fluids as the cleaning liquid.

Furthermore, in the above embodiment, although it is illustrated to perform pre-drying in the cleaning tank 5, it is possible to perform only a main drying in the drying tank 6a without performing the pre-drying. Also, although it is illustrated to spray dry air as pre-drying, the present disclosure is not limited thereto, and it is possible to perform pre-drying by rotating the FOUP 20 and blowing the cleaning liquid by centrifugal force.

From the foregoing content, it will be appreciated that various embodiments of the present disclosure have been described herein for purposes of illustration, and that various modifications can be made without departing from the scope and spirit of the present disclosure. Accordingly, the various embodiments disclosed herein are not intended to be limiting, with the true scope and spirit being indicated by the following claims.

What is claimed is:

1. A wafer storage container drying apparatus comprising a drying tank for drying a wafer storage container that has a storage space connected to an opening and configured to store a wafer, and includes a body including a flange gripped by a robot, and a door installed to be openable and closable with respect to the opening,
wherein the drying tank includes,
a carrying-in/out port configured to be openable and closable by an opening and closing cover;
a body receiver configured to receive the body of the wafer storage container in a state where the flange faces the carrying-in/out port; and
a door holder provided closer to the carrying-in/out port of the body receiver than the body of the wafer storage container in a state where the body of the wafer storage container is received in the body receiver, and configured to hold the door such that each side of the door is neither orthogonal nor parallel to one side that forms the carrying-in/out port, when the drying tank is viewed in a plan view.

2. The wafer storage container drying apparatus according to claim 1, wherein the door holder is provided to hold each of two diagonally opposite corners among four corners of the door.

3. The wafer storage container drying apparatus according to claim 2, wherein the door is carried via the carrying-in/out port by the robot, and
wherein a gap is formed between each of two opposing sides forming the carrying-in/out port, where the door holder is provided, and the door held by the door holder, and allows a gripping portion of the robot to be inserted thereinto.

4. The wafer storage container drying apparatus according to claim 2, wherein the door holder is provided near each of the two opposing sides forming the carrying-in/-out port, and a space between the door holders has a size such that the body of the wafer storage container is able to be carried into the body receiver, and the body of the wafer storage container is able to be carried out of the body receiving unit in a state where the flange faces toward the the carrying-in/out port.

5. The wafer storage container drying apparatus according to claim 1, further comprising:
an exhaust port configured to exhaust an internal space of the drying tank; and
a heater provided in the drying tank and configured to heat the drying tank,
wherein the internal space of the drying tank is heated by the heater while being exhausted to a predetermined pressure by the exhaust port.

6. A cleaning system comprising:
the wafer storage container drying apparatus according to claim 1; and
a cleaning tank for cleaning the wafer storage container,
wherein the drying tank dries the wafer storage container that is cleaned in the cleaning tank.
